(19) United States
(12) Patent Application Publication
(10) Pub. No.: US 2018/0274096 A1
(43) Pub. Date: Sep. 27, 2018

(54) SYSTEM AND METHOD FOR ATOMIC LAYER DEPOSITION

(71) Applicant: ISAC RESEARCH INC., Daejeon (KR)

(72) Inventors: Hyung Sang PARK, Seoul (KR); Tae Ho YOON, Gyeonggi-do (KR); Ji Hye KIM, Daejeon (KR)

(21) Appl. No.: 15/934,115

(22) Filed: Mar. 23, 2018

(30) Foreign Application Priority Data
Mar. 27, 2017 (KR) 10-2017-0038228

(51) Int. Cl. C23C 16/455; H01L 21/02

(52) U.S. Cl. CPC C23C 16/45551; H01L 21/0228; C23C 16/45589

(57) ABSTRACT

Disclosed is an atomic layer deposition system and method, the system including a chamber having a first accommodation space to accommodate a first target substrate, and a first gas supplier mounted in the chamber to supply a first gas to the first target substrate, wherein the first gas supplier includes a first fixed block having a rotation space therein and including a (1-1)^{st} passage provided in a first direction of the rotation space and a (1-2)^{nd} passage provided in a second direction of the rotation space, and a first rotatable pipe having a first gas channel therein, having a pipe shape including at least one first gas outlet at a side thereof, and rotatably mounted in the rotation space of the first fixed block to connect the first gas outlet to the (1-1)^{st} or (1-2)^{nd} passage of the first fixed block.

### CROSS-REFERENCE TO RELATED PATENT APPLICATION

This application claims the benefit of Korean Patent Application No. 10-2017-0038228, filed on Mar. 27, 2017, in the Korean Intellectual Property Office, the disclosure of which is incorporated herein in its entirety by reference.

### BACKGROUND

### 1. Field

The present invention relates to an atomic layer deposition system and method and, more particularly, to an atomic layer deposition system and method capable of rapidly switching gases by using a rotatable pipe having a gas outlet.

### 2. Description of the Related Art

Due to development of semiconductor integration technology, deposition of a high-purity and high-quality thin film is regarded as a significant part of a semiconductor manufacturing process. Representative thin film deposition methods include chemical vapour deposition (CVD) and physical vapour deposition (PVD). The PVD method such as sputtering has poor step coverage on a deposited thin film and thus cannot be used to deposit a uniform-thickness film on an uneven surface.

The CVD method causes reaction between gas-phase materials on the surface of a heated substrate, and deposits a compound generated due to the reaction, on the substrate surface. Compared to the PVD method, the CVD method has better step coverage, less damages the substrate on which the thin film is deposited, requires less deposition costs, is more appropriate for mass production, and thus is used a lot.

However, since the integration density of semiconductor devices is currently increased to a sub-micron level, the conventional CVD method is not sufficient to achieve a uniform thickness of a sub-micron level or excellent step coverage on a wafer substrate, and cannot easily deposit a material film having a constant composition irrespective of locations when sub-micron-sized steps such as contact holes, vias, or trenches are present in the wafer substrate.

Therefore, unlike the conventional CVD method in which all process gases are injected at the same time, a time-division atomic layer deposition method in which two or more process gases required to obtain a desired thin film are sequentially supplied based on time not to meet each other in gas phases and supply cycles thereof are periodically repeated to deposit a thin film is used as a new thin film deposition method.

In addition, a space-division atomic layer deposition in which two or more process gases are supplied to different spaces not to meet each other in gas phases and a substrate is sequentially moved to the different spaces is also used.

In a time-division atomic layer deposition system, switching valves capable of switching various gases such as a purge gas, a reaction gas, and a source gas based on time are mounted. However, general switching valves require much time to purge previously used gases remaining in pipes between the switching valves and a reactor or in a shower head, or cannot sufficiently purge the gases due to complicated valve structures.

Furthermore, since the conventional switching valves generally use diaphragm-type gas valves and diaphragms are easily deformed due to repeated use thereof, component durability can be reduced and a switching time cannot be easily reduced. As such, production time and costs are increased and thus productivity is greatly reduced.

### SUMMARY

The present invention provides an atomic layer deposition system and method capable of not only producing high-quality products but also maximizing productivity by rapidly switching gases without a supply pipe purging process and achieving a very short gas supply time to reduce a cycle time based on rotation of a rotatable pipe having a gas outlet instead of transformation of a diaphragm. However, the scope of the present invention is not limited thereto.

According to an aspect of the present invention, there is provided an atomic layer deposition system including a chamber having a first accommodation space to accommodate a first target substrate, and a first gas supplier mounted in the chamber to supply a first gas to the first target substrate, wherein the first gas supplier includes a first fixed block having a rotation space therein and including a (1-1)^{st} passage provided in a first direction of the rotation space and a (1-2)^{nd} passage provided in a second direction of the rotation space, and a first rotatable pipe having a first gas channel therein, having a pipe shape including at least one first gas outlet at a side thereof, and rotatably mounted in the rotation space of the first fixed block to connect the first gas outlet to the (1-1)^{st} or (1-2)^{nd} passage of the first fixed block.

A first heater block for placing the first target substrate thereon may be mounted in the chamber, and the first gas supplier and a first purge gas supplier may be mounted at a side of the chamber and a first gas exhauster may be mounted at another side of the chamber in such a manner that one or more types of gases flow from a left side to a right side or from a right side to a left side along a surface of the first target substrate.

The atomic layer deposition system may further include a second gas supplier mounted adjacent to the first gas supplier and mounted in the chamber to supply a second gas to the first target substrate, and the second gas supplier may include a second fixed block having a rotation space therein and including a (2-1)^{st} passage provided in a first direction of the rotation space and a (2-2)^{nd} passage provided in a second direction of the rotation space, and a second rotatable pipe having a second gas channel therein, having a pipe shape including at least one second gas outlet at a side thereof, and rotatably mounted in the rotation space of the second fixed block to connect the second gas outlet to the (2-1)^{st} or (2-2)^{nd} passage of the second fixed block.

The (1-1)^{st} passage of the first gas supplier and the (2-1)^{st} passage of the second gas supplier may be connected to the first accommodation space in such a manner that the first or second gas is supplied to the first target substrate based on rotation of the first and second rotatable pipes, and the (1-2)^{nd} passage of the first gas supplier and the (2-2)^{nd} passage of the second gas supplier may be connected to pump lines in such a manner that the first or second gas is not supplied to the first target substrate but is directly discharged outside the chamber based on rotation of the first and second rotatable pipes.

The chamber may have the first accommodation space to accommodate the first target substrate and the first heater block, and have a second accommodation space provided above or below the first accommodation space with respect to a separation plate to accommodate a second target substrate and a second heater block.

A second purge gas supplier may be mounted at a side of the second accommodation space of the chamber, a second gas exhauster may be mounted at another side of the second accommodation space, and the first and second gas suppliers may be mounted between the first and second accommodation spaces.

The (1-1)^{st} passage of the first gas supplier and the (2-1)^{st} passage of the second gas supplier may be connected to the first accommodation space and the (1-2)^{nd} passage of the first gas supplier and the (2-2)^{nd} passage of the second gas supplier may be connected to the second accommodation space in such a manner that the first or second gas is supplied to the first target substrate once and is supplied to the second target substrate next time based on rotation of the first rotatable pipe of the first gas supplier and the second rotatable pipe of the second gas supplier.

The first fixed block may include an expanded space part having a width greater than a width of the (1-2)^{nd} passage and less than a width of the rotation space, between the rotation space and the (1-2)^{nd} passage.

According to another aspect of the present invention, there is provided an atomic layer deposition method of an atomic layer deposition system including a chamber having a first accommodation space to accommodate a first target substrate and having a second accommodation space to accommodate a second target substrate, and a first gas supplier mounted in the chamber to supply a first gas to the first or second target substrate, the method including a first step of supplying the first gas to the first target substrate by rotating a first rotatable pipe, which is rotatably mounted in a first fixed block having a rotation space therein and including a (1-1)^{st} passage provided in a first direction of the rotation space and a (1-2)^{nd} passage provided in a second direction of the rotation space, to connect a first gas outlet to the (1-1)^{st} passage of the first fixed block, and a second step of discharging the first gas outside or supplying the first gas to the second target substrate by rotating the first rotatable pipe to connect the first gas outlet to the (1-2)^{nd} passage of the first fixed block.

### BRIEF DESCRIPTION OF THE DRAWINGS

The above and other features and advantages of the present invention will become more apparent by describing in detail embodiments thereof with reference to the attached drawings in which:

FIG. 1 is a perspective view of a first gas supplier of an atomic layer deposition system, according to some embodiments of the present invention;

FIG. 2 is a perspective view of a first rotatable pipe of the first gas supplier of FIG. 1;

FIG. 3 is a cross-sectional view of the first gas supplier of FIG. 1;

FIG. 4 is a cross-sectional view showing a first mode of an atomic layer deposition system according to some embodiments of the present invention;

FIG. 5 is a magnified cross-sectional view of the first gas supplier and a second gas supplier of FIG. 4;

FIG. 6 is a cross-sectional view showing a second mode of the atomic layer deposition system of FIG. 4;

FIG. 7 is a cross-sectional view showing a first mode of an atomic layer deposition system according to other embodiments of the present invention;

FIG. 8 is a magnified cross-sectional view of the first gas supplier and the second gas supplier of FIG. 7; and

FIG. 9 is a cross-sectional view showing a second mode of the atomic layer deposition system of FIG. 7.

### DETAILED DESCRIPTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity.

The terminology used herein is for the purpose of describing particular embodiments and is not intended to limit the invention. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

An atomic layer deposition system and method according to various embodiments of the present invention will now be described with reference to the drawings.

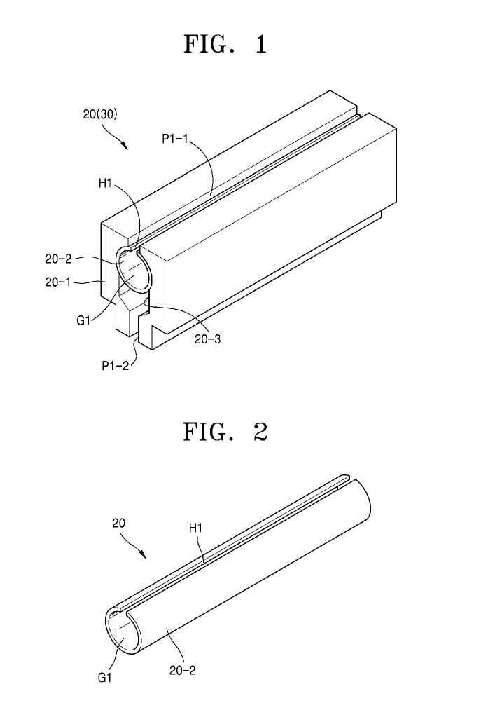

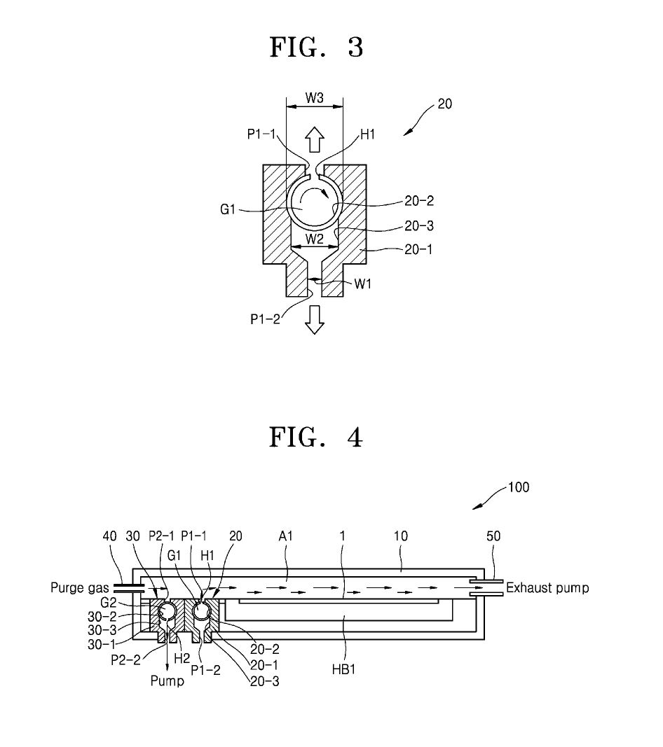

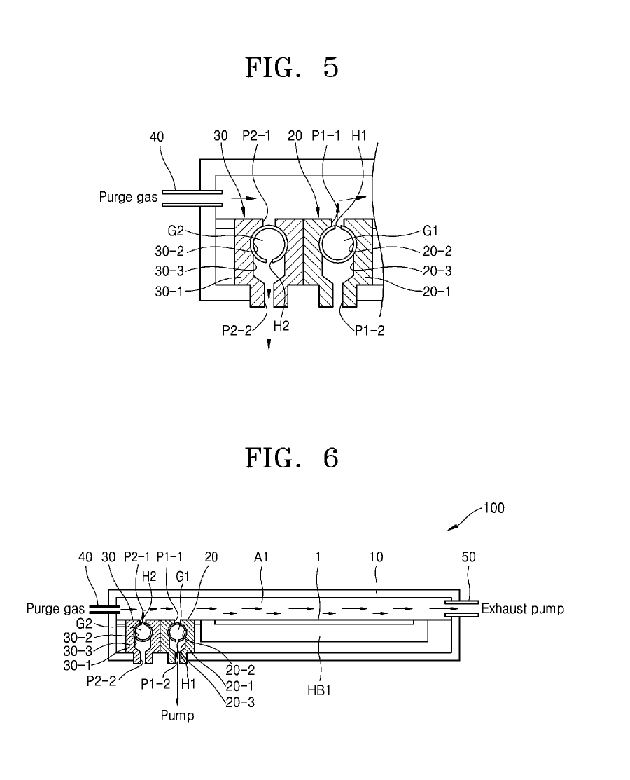

FIG. 1 is a perspective view of a first gas supplier 20 of an atomic layer deposition system, according to some embodiments of the present invention, FIG. 2 is a perspective view of a first rotatable pipe 20-2 of the first gas supplier 20 of FIG. 1, FIG. 3 is a cross-sectional view of the first gas supplier 20 of FIG. 1, FIG. 4 is a cross-sectional view showing a first mode of an atomic layer deposition system 100 according to some embodiments of the present invention, and FIG. 5 is a magnified cross-sectional view of the first gas supplier 20 and a second gas supplier 30 of FIG. 4.

Referring to FIGS. 1 to 5, the atomic layer deposition system 100 according to some embodiments of the present invention may include a chamber 10, the first gas supplier 20, and the second gas supplier 30 as illustrated in FIG. 4.

For example, as illustrated in FIG. 4, the chamber 10 has a first accommodation space A1 to accommodate a first target substrate 1, and may be a structure which has sufficient durability and strength such that one of various vacuum pumps, gas suppliers, temperature control devices, etc. is mountable therein to obtain a vacuum environment or a deposition environment.

The first accommodation space A1 of the chamber 10 may be configured to accommodate not only the first target substrate 1 but also a part or the entirety of the above-described first and second gas suppliers 20 and 30.

The first accommodation space A1 of the chamber 10 may also be configured to accommodate the first target substrate 1 and a first heater block HB1. Therefore, temperature of the first target substrate 1 may be controlled using the first heater block HB1 in a deposition process on the first target substrate 1.

Although not shown in FIGS. 1 to 5, the chamber 10 may have one of various gates, doors, covers, etc. through which the first target substrate 1 enters and exits.

For example, as illustrated in FIGS. 1 to 5, the first gas supplier 20 is mounted in the chamber 10 to supply a first gas to the first target substrate 1. Specifically, as illustrated in FIGS. 1 to 3, the first gas supplier 20 may include a first fixed block 20-1 having a rotation space therein and including a (1-1)^{st} passage P1-1 provided in a first direction of the rotation space and a (1-2)^{nd} passage P1-2 provided in a second direction of the rotation space, and the first rotatable pipe 20-2 having a first gas channel G1 therein, having a pipe shape including at least one first gas outlet H1 at a side thereof, and rotatably mounted in the rotation space of the first fixed block 20-1 to connect the first gas outlet H1 to the (1-1)^{st} or (1-2)^{nd} passage P1-1 or P1-2 of the first fixed block 20-1.

Therefore, the first gas may be selectively discharged, for example, upward from the first fixed block 20-1 through the (1-1)^{st} passage P1-1 when the first gas outlet H1 of the first rotatable pipe 20-2 is rotated to face upward, and be selectively discharged, for example, downward from the first fixed block 20-1 through the (1-2)^{nd} passage P1-2 when the first gas outlet H1 of the first rotatable pipe 20-2 is rotated to face downward. That is, a path of supplying the first gas may be switched to upward or downward based on a rotation angle of the first rotatable pipe 20-2.

Accordingly, the first rotatable pipe 20-2 may be rotated to switch gases at a much higher speed compared to a typical method of forcibly transforming a diaphragm. Since this switching method based on rotation does not transform any component, the component may be semi-permanently used. In addition, since repeated tests show that a single cycle time of about 0.25 sec. is achieved when the first rotatable pipe 20-2 is rotated, for example, at a rotation speed of 240 rpm, a switching speed may be significantly increased.

As illustrated in FIG. 3, a switching timing based on the rotation angle may be controlled by adjusting widths of the (1-1)^{st} and (1-2)^{nd} passages P1-1 and P1-2. For example, to increase a period of discharging the first gas outside, the first fixed block 20-1 may include an expanded space part 20-3 having a width W2 greater than a width W1 of the (1-2)^{nd} passage P1-2 and less than a width W3 of the rotation space, between the rotation space and the (1-2)^{nd} passage P1-2. The width W2 of the expanded space part 20-3 may be optimally designed based on a gas discharge time, a deposition environment, or the like.

The (1-1)^{st} and (1-2)^{nd} passages P1-1 and P1-2 are provided at an angle of 180° with respect to the first rotatable pipe 20-2 in FIGS. 1 to 5, but may also be provided at various angles depending on environments.

As illustrated in FIGS. 4 and 5, in the atomic layer deposition system 100 according to some embodiments of the present invention, the first heater block HB1 for placing the first target substrate 1 thereon may be mounted in the chamber 10, and the first gas supplier 20 and a first purge gas supplier 40 may be mounted at a side of the chamber 10 and a first gas exhauster 50 may be mounted at the other side of the chamber 10 in such a manner that one or more types of gases may flow from a left side to a right side or from a right side to a left side along the surface of the first target substrate 1.

As illustrated in FIGS. 4 and 5, in the atomic layer deposition system 100 according to some embodiments of the present invention, the second gas supplier 30 is mounted adjacent to the first gas supplier 20 and is mounted in the chamber 10 to supply a second gas to the first target substrate 1, and may have the same structure and function as the above-described first gas supplier 20.

Specifically, for example, the second gas supplier 30 may include a second fixed block 30-1 having a rotation space therein and including a (2-1)^{st} passage P2-1 provided in a first direction of the rotation space and a (2-2)^{nd} passage P2-2 provided in a second direction of the rotation space, and a second rotatable pipe 30-2 having a second gas channel G2 therein, having a pipe shape including at least one second gas outlet H2 at a side thereof, and rotatably mounted in the rotation space of the second fixed block 30-1 to connect the second gas outlet H2 to the (2-1)^{st} or (2-2)^{nd} passage P2-1 or P2-2 of the second fixed block 30-1.

Specifically, for example, as illustrated in FIG. 4, the (1-1)^{st} passage P1-1 of the first gas supplier 20 and the (2-1)^{st} passage P2-1 of the second gas supplier 30 may be connected to the first accommodation space A1 in such a manner that the first or second gas is supplied to the first target substrate 1 based on rotation of the first and second rotatable pipes 20-2 and 30-2, and the (1-2)^{nd} passage P1-2 of the first gas supplier 20 and the (2-2)^{nd} passage P2-2 of the second gas supplier 30 may be connected to pump lines in such a manner that the first or second gas is not supplied to the first target substrate 1 but is directly discharged outside the chamber 10 based on rotation of the first and second rotatable pipes 20-2 and 30-2.

FIG. 6 is a cross-sectional view showing a second mode of the atomic layer deposition system 100 of FIG. 4.

Therefore, as illustrated in FIGS. 4 and 6, operation of the atomic layer deposition system 100 according to some embodiments of the present invention will now be described. Initially, as shown in the first mode of FIG. 4, the first gas may be supplied to the first target substrate 1 by rotating the first rotatable pipe 20-2, which is rotatably mounted in the first fixed block 20-1 having the rotation space therein and including the (1-1)^{st} passage P1-1 provided in the first direction of the rotation space and the (1-2)^{nd} passage P1-2 provided in the second direction of the rotation space, upward to connect the first gas outlet H1 to the (1-1)^{st} passage P1-1 of the first fixed block 20-1. In this case, the second gas may be directly discharged outside the chamber 10 by rotating the second rotatable pipe 30-2 of the second gas supplier 30 downward. Herein, the first gas may be a source gas, and the second gas may be a reaction gas. However, the first and second gases are not limited thereto and various gases may be used.

Then, after or simultaneously with a purge process, as shown in the second mode of FIG. 6, the first gas may be directly discharged outside the chamber 10 by rotating the first rotatable pipe 20-2 downward to connect the first gas outlet H1 to the (1-2)^{nd} passage P1-2 of the first fixed block 20-1. In this case, the second gas may be supplied to the first target substrate 1 by rotating the second rotatable pipe 30-2 of the second gas supplier 30 upward.

Accordingly, not only may high-quality products be produced but also may productivity be maximized by rapidly switching gases without a supply pipe purging process and achieving a very short gas supply time to reduce a cycle time based on rotation of the first and second rotatable pipes 20-2 and 30-2 having the first and second gas outlets H1 and H2 instead of transformation of a diaphragm.

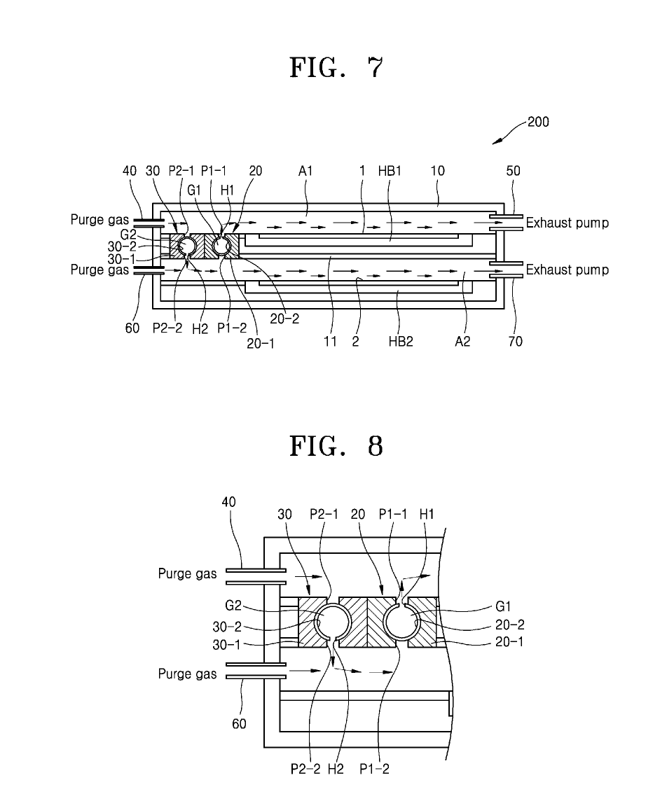

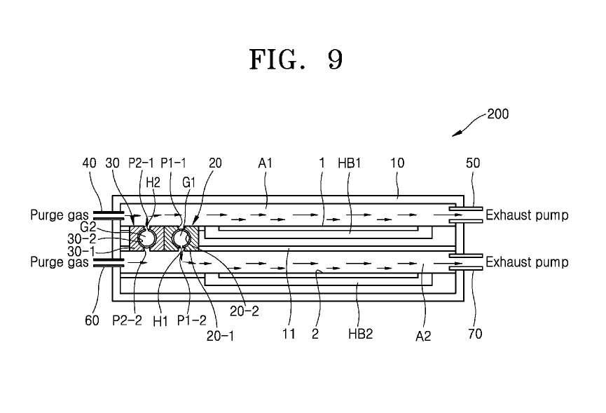

FIG. 7 is a cross-sectional view showing a first mode of an atomic layer deposition system 200 according to other embodiments of the present invention, FIG. 8 is a magnified cross-sectional view of the first gas supplier 20 and the second gas supplier 30 of FIG. 7, and FIG. 9 is a cross-sectional view showing a second mode of the atomic layer deposition system 200 of FIG. 7.

As illustrated in FIGS. 7 to 9, in the atomic layer deposition system 200 according to other embodiments of the present invention, the chamber 10 may have the first accommodation space A1 to accommodate the first target substrate 1 and the first heater block HB1, and have a second accommodation space A2 provided above or below the first accommodation space A1 with respect to a separation plate 11 to accommodate a second target substrate 2 and a second heater block HB2.

Specifically, a second purge gas supplier 60 may be mounted at a side of the second accommodation space A2 of the chamber 10, a second gas exhauster 70 may be mounted at the other side of the second accommodation space A2, and the first and second gas suppliers 20 and 30 may be mounted between the first and second accommodation spaces A1 and A2.

As illustrated in FIGS. 7 to 9, in the atomic layer deposition system 200 according to other embodiments of the present invention, the (1-1)^{st} passage P1-1 of the first gas supplier 20 and the (2-1)^{st} passage P2-1 of the second gas supplier 30 may be connected to the first accommodation space A1 and the (1-2)^{nd} passage P1-2 of the first gas supplier 20 and the (2-2)^{nd} passage P2-2 of the second gas supplier 30 may be connected to the second accommodation space A2 in such a manner that the first or second gas is supplied to the first target substrate 1 once and is supplied to the second target substrate 2 next time based on rotation of the first rotatable pipe 20-2 of the first gas supplier 20 and the second rotatable pipe 30-2 of the second gas supplier 30.

Although not additionally shown, an atomic layer deposition method according to some embodiments of the present invention is an atomic layer deposition method of the atomic layer deposition system 100 including the chamber 10 having the first accommodation space A1 to accommodate the first target substrate 1 and having the second accommodation space A2 to accommodate the second target substrate 2, and the first gas supplier 20 mounted in the chamber 10 to supply the first gas to the first or second target substrate 1 or 2, and includes a first step of supplying the first gas to the first target substrate 1 by rotating the first rotatable pipe 20-2, which is rotatably mounted in the first fixed block 20-1 having the rotation space therein and including the (1-1)^{st} passage P1-1 provided in the first direction of the rotation space and the (1-2)^{nd} passage P1-2 provided in the second direction of the rotation space, to connect the first gas outlet H1 to the (1-1)^{st} passage P1-1 of the first fixed block 20-1, and a second step of discharging the first gas outside or supplying the first gas to the second target substrate 2 by rotating the first rotatable pipe 20-2 to connect the first gas outlet H1 to the (1-2)^{nd} passage P1-2 of the first fixed block 20-1.

According to the above-described embodiments of the present invention, not only may high-quality products be produced but also may productivity be maximized by rapidly switching gases without a supply pipe purging process and achieving a very short gas supply time to reduce a cycle time based on rotation of a rotatable pipe having a gas outlet instead of transformation of a diaphragm. However, the scope of the present invention is not limited to the above-described effect.

While the present invention has been particularly shown and described with reference to embodiments thereof, it will be understood by one of ordinary skill in the art that various changes in form and details may be made therein without departing from the spirit and scope of the present invention as defined by the following claims.

What is claimed is:

1. An atomic layer deposition system comprising:
a chamber having a first accommodation space to accommodate a first target substrate; and
a first gas supplier mounted in the chamber to supply a first gas to the first target substrate,
wherein the first gas supplier comprises:
a first fixed block having a rotation space therein and comprising a (1-1)^{st} passage provided in a first direction of the rotation space and a (1-2)^{nd} passage provided in a second direction of the rotation space; and
a first rotatable pipe having a first gas channel therein, having a pipe shape comprising at least one first gas outlet at a side thereof, and rotatably mounted in the rotation space of the first fixed block to connect the first gas outlet to the (1-1)^{st} or (1-2)^{nd} passage of the first fixed block.

2. The atomic layer deposition system of claim 1, wherein a first heater block for placing the first target substrate thereon is mounted in the chamber, and
wherein the first gas supplier and a first purge gas supplier are mounted at a side of the chamber and a first gas exhauster is mounted at another side of the chamber in such a manner that one or more types of gases flow from a left side to a right side or from a right side to a left side along a surface of the first target substrate.

3. The atomic layer deposition system of claim 2, further comprising a second gas supplier mounted adjacent to the first gas supplier and mounted in the chamber to supply a second gas to the first target substrate,
wherein the second gas supplier comprises:
a second fixed block having a rotation space therein and comprising a (2-1)^{st} passage provided in a first direction of the rotation space and a (2-2)^{nd} passage provided in a second direction of the rotation space; and
a second rotatable pipe having a second gas channel therein, having a pipe shape comprising at least one second gas outlet at a side thereof, and rotatably mounted in the rotation space of the second fixed block to connect the second gas outlet to the (2-1)^{st} or (2-2)^{nd} passage of the second fixed block.

4. The atomic layer deposition system of claim 3, wherein the (1-1)^{st} passage of the first gas supplier and the (2-1)^{st} passage of the second gas supplier are connected to the first accommodation space in such a manner that the first or second gas is supplied to the first target substrate based on rotation of the first and second rotatable pipes, and
wherein the (1-2)^{nd} passage of the first gas supplier and the (2-2)^{nd} passage of the second gas supplier are connected to pump lines in such a manner that the first or second gas is not supplied to the first target substrate but is directly discharged outside the chamber based on rotation of the first and second rotatable pipes.

5. The atomic layer deposition system of claim 3, wherein the chamber has the first accommodation space to accommodate the first target substrate and the first heater block, and has a second accommodation space provided above or below the first accommodation space with respect to a separation plate to accommodate a second target substrate and a second heater block.

6. The atomic layer deposition system of claim 5, wherein a second purge gas supplier is mounted at a side of the second accommodation space of the chamber,
wherein a second gas exhauster is mounted at another side of the second accommodation space, and
wherein the first and second gas suppliers are mounted between the first and second accommodation spaces.

7. The atomic layer deposition system of claim 6, wherein the (1-1)^{st} passage of the first gas supplier and the (2-1)^{st} passage of the second gas supplier are connected to the first accommodation space and the (1-2)^{nd} passage of the first gas supplier and the (2-2)^{nd} passage of the second gas supplier are connected to the second accommodation space in such a manner that the first or second gas is supplied to the first target substrate once and is supplied to the second target substrate next time based on rotation of the first rotatable pipe of the first gas supplier and the second rotatable pipe of the second gas supplier.

8. The atomic layer deposition system of claim 1, wherein the first fixed block comprises an expanded space part having a width greater than a width of the (1-2)^{nd} passage and less than a width of the rotation space, between the rotation space and the (1-2)^{nd} passage.

9. An atomic layer deposition method of an atomic layer deposition system comprising a chamber having a first accommodation space to accommodate a first target substrate and having a second accommodation space to accommodate a second target substrate, and a first gas supplier mounted in the chamber to supply a first gas to the first or second target substrate, the method comprising:
a first step of supplying the first gas to the first target substrate by rotating a first rotatable pipe, which is rotatably mounted in a first fixed block having a rotation space therein and comprising a (1-1)^{st} passage provided in a first direction of the rotation space and a (1-2)^{nd} passage provided in a second direction of the rotation space, to connect a first gas outlet to the (1-1)^{st} passage of the first fixed block; and
a second step of discharging the first gas outside or supplying the first gas to the second target substrate by rotating the first rotatable pipe to connect the first gas outlet to the (1-2)^{nd} passage of the first fixed block.
